(19) United States
(12) Patent Application Publication
(10) Pub. No.: US 2026/0190927 A1
(43) Pub. Date: Jul. 2, 2026

(54) TRAY APPARATUS FOR TRANSFERRING SUBSTRATE

(71) Applicant: Absolics Inc., Covington, GA (US)

(72) Inventors: BYUNGJOO PARK, Covington, GA (US); Chaemook LIM, Covington, GA (US); MINHO JI, Covington, GA (US)

(73) Assignee: Absolics Inc., Covington, GA (US)

(21) Appl. No.: 19/414,279

(22) Filed: Dec. 10, 2025

Related U.S. Application Data
(60) Provisional application No. 63/739,121, filed on Dec. 27, 2024.

(51) Int. Cl. H10P 72/10

(52) U.S. Cl. CPC H10P 72/18

(57) ABSTRACT

A tray apparatus for transferring a substrate is provided, comprising: a fixed tray comprising a plate-shaped fixed frame having a shape corresponding to the substrate, and configured to seat the substrate while supporting a bottom surface of the substrate in a state of being spaced apart by a predetermined height from the fixed frame; and an inner tray comprising a plate-shaped inner frame corresponding to the substrate, the inner tray being coupled in a state of being stacked on the fixed frame so as to be in a state of being spaced apart from the substrate, the inner frame being brought into close contact with the bottom surface of the substrate while being lifted by a substrate carrier so as to separate the substrate from the fixed tray, and the inner tray being transferred together with the substrate by the substrate carrier.

### CROSS-REFERENCE TO RELATED APPLICATION

This application claims priority of U.S. Provisional Patent Application No. 63/739,121, filed on Dec. 27, 2024, the entire disclosure of which is hereby incorporated by reference for all purposes.

### BACKGROUND

### Technical Field

Embodiments disclosed in the present specification relate to a tray apparatus for transferring a substrate, and more particularly to a tray apparatus which provides a seating region for a substrate and a traction region that allows a seated substrate to be indirectly transferred without direct contact between the substrate and a substrate carrier.

### Description of Related Art

Four core technologies of the semiconductor industry that have enabled the rapid development of electronic products are semiconductor technology, semiconductor packaging technology, manufacturing process technology, and software technology.

Semiconductor technology has been developed in various forms, such as line widths on the micron or sub-micron nano scale, cells in numbers of ten million or more, high-speed operation, and a large amount of heat generation. However, technology for perfectly packaging such semiconductor devices has not been supported to a comparable degree.

Accordingly, the electrical performance of a semiconductor is sometimes determined by packaging technology and electrical connection according thereto, rather than by the performance of the semiconductor technology itself.

Recently, attempts have been made to industrially apply a glass substrate (glass core) as a high-end packaging substrate. Such glass substrates become the subject of precise quality inspection at intermediate stages of each process in an automated process, and for this purpose, procedures of transferring the glass substrate to an optical stage for inspection are frequently required.

When performing precise inspection of sample substrates, conventionally, an operator directly extracted a sample substrate by hand, loaded it on a carrier tray, transferred it to an optical stage, lifted the sample substrate again, placed it on the optical stage, and then performed precise inspection using an optical device.

Accordingly, in the related art, because an operator directly transferred the sample substrate by hand, contamination due to fingerprints occurred, and there was a problem that the glass substrate was damaged in the process of being moved by hand.

Therefore, in recent years, technologies for automatically transferring a substrate, such as a substrate transfer tray disclosed in Korean Registered Patent Publication No. 10-1318172, have been proposed. The related art comprises a frame in which a substrate is mounted, and an adhesion and separation unit provided on a surface of the frame facing the substrate, the adhesion and separation unit adhering the substrate or separating the adhered substrate. The substrate is fixed to or separated from the frame by air pressure in an adhesion pad and an air suction/supply passage.

According to such related art, the substrate is fixed in an upright state to the tray through the adhesion and separation unit and is then transferred. In this process, since the tray has to be transferred while maintaining the air pressure of the air suction/supply passage, there is a problem in that implementation of a transfer line is complicated and construction costs are high.

In addition, in the related art, when precisely inspecting a plurality of substrates, it is necessary to separate a substrate from the tray, place the substrate on the optical stage, perform inspection, fix the substrate to the tray again, transfer the substrate back to its original position, and then inspect the next substrate, and thus there is a problem in that the inspection procedure and inspection time increase.

Accordingly, there has been a need for technology for solving the above-described problems.

Meanwhile, the aforementioned background art is technical information that was possessed by the inventor for deriving the present invention or acquired in the course of deriving the present invention, and it cannot necessarily be regarded as publicly known technology that was disclosed to the general public prior to the filing of the present invention.

### SUMMARY

In some embodiments, a tray apparatus for transferring a substrate, which allows the substrate to be safely transferred without a risk of the substrate being contaminated or damaged in the course of transfer of the substrate is provided.

In some embodiments, a tray apparatus for transferring a substrate, which allows the substrate to be transferred while the substrate is seated on a tray without direct contact with a substrate carrier is provided.

In some embodiments, a tray apparatus for transferring a substrate, which allows an optical inspection to be safely performed while the substrate is seated on an inner tray is provided.

Embodiments disclosed in the present specification are further directed to providing a tray apparatus for transferring a substrate, which allows the substrate to be transferred without contact with a substrate carrier through a fixed tray on which the substrate is seated and an inner tray which is raised by the substrate carrier and separates the substrate from the fixed tray.

Embodiments disclosed in the present specification are further directed to providing a tray apparatus for transferring a substrate, which allows the substrate to be supported in a state of being spaced apart from a bottom surface through seating protrusions provided on the fixed tray, and which allows the substrate to be separated from the seating protrusions and transferred together with the inner tray through raising of the inner tray stacked on the fixed tray.

Embodiments disclosed in the present specification are further directed to providing a tray apparatus for transferring a substrate, which allows the substrate to be supported in a correctly positioned state in the course of the inner tray being raised by the substrate carrier, and which can prevent lateral movement of the substrate in the course of transferring the substrate.

Embodiments disclosed in the present specification are further directed to providing a tray apparatus for transferring a substrate, which allows the inner tray to support the substrate while preventing damage to edge portions of the substrate.

Embodiments disclosed in the present specification are further directed to providing a tray apparatus for transferring a substrate, which allows the inner tray to support the substrate while preventing warpage or sagging of a central portion of the substrate.

Embodiments disclosed in the present specification are further directed to providing a tray apparatus for transferring a substrate, which allows inspection by an optical device in a state in which the substrate is placed on the inner tray by supporting an outer peripheral portion or a dummy region of a central portion, which are not product regions, while the inner tray supports the substrate.

A tray apparatus for transferring a substrate according to one embodiment may comprise: a fixed tray comprising a plate-shaped fixed frame having a shape corresponding to the substrate, and configured to seat the substrate while supporting a bottom surface of the substrate in a state of being spaced apart by a predetermined height from the fixed frame; and an inner tray comprising a plate-shaped inner frame corresponding to the substrate, the inner tray being coupled in a state of being stacked on the fixed frame so as to be in a state of being spaced apart from the substrate, the inner frame being brought into close contact with the bottom surface of the substrate while being lifted by a substrate carrier so as to separate the substrate from the fixed tray, and the inner tray being transferred together with the substrate by the substrate carrier.

The fixed tray may further comprise a plurality of seating protrusions which are formed to protrude in a vertical direction from the fixed frame and support the substrate in a state of being spaced apart from the fixed frame.

The inner tray may further comprise a protrusion holder which is formed in the inner frame as a groove or a hole corresponding to a horizontal cross section of the seating protrusions, and which surrounds an outer periphery of the seating protrusions and is coupled to the seating protrusions such that the seating protrusions are exposed upward when the inner tray is coupled in a state of being stacked on the fixed frame.

The seating protrusions may comprise outer protrusions which are formed to protrude in a vertical direction at an outer periphery of the fixed frame and support an outer peripheral portion of the substrate from below and from a lateral side.

The outer protrusions may comprise: a protrusion main body which protrudes by a predetermined height in a vertical direction from an upper surface of the fixed frame; and an angle protrusion which protrudes in a horizontal direction at a predetermined height of the protrusion main body and supports the outer peripheral portion of the substrate while forming an angle shape together with the protrusion main body.

The seating protrusions may further comprise central protrusions which are formed to protrude in a vertical direction at a central portion of the fixed frame and support a central portion of the substrate from below, and a height of the central protrusions may correspond to a height at which the angle protrusions are formed.

The inner frame may comprise a central support which is formed in a manner of extending across a center of the inner frame and on which the protrusion holder is formed, and the central support may comprise a sag-preventing protrusion which is formed to protrude on an upper surface and prevents sagging of a central portion of a bottom surface of the substrate by being brought into close contact with the central portion of the bottom surface of the substrate when the inner frame is raised.

The inner tray may further comprise a substrate step which is formed in a stepped shape to form a level difference on an upper surface of the inner frame along a circumference of the substrate, and which supports a side surface of the substrate and suppresses lateral movement of the substrate in the course of raising of the inner tray by the substrate carrier.

The substrate step may comprise: a vertical portion which extends in a vertical direction from the upper surface of the inner frame and supports the side surface of the substrate; and an inclined portion which extends while forming an incline from the vertical portion and guides the substrate toward the vertical portion when the inner frame is raised.

The inner tray may further comprise a rounded portion which is formed in a circular shape at a corner portion of the substrate step and spaces a corner portion of the substrate apart from the substrate step.

The inner tray may further comprise transfer wings which are formed to protrude outward in a horizontal direction from the inner frame and are drawn by the substrate carrier when being transferred by the substrate carrier.

The transfer wings may be formed so as to surround, from an outer side, the protrusion holder which is coupled to the outer protrusions.

The substrate may be a semiconductor substrate comprising a glass core or glass layer.

The substrate may be a and/or a semiconductor packaging substrate comprising a glass core. The glass core may comprise plate-shaped glass, for example borosilicate glass, aluminosilicate glass, or alkali-free glass, without being limited thereto.

The inner tray may support a dummy region, which is not a product region, among regions of the substrate, and may allow inspection of the substrate by an optical device.

### BRIEF DESCRIPTION OF THE DRAWINGS

FIG. 1 is an exploded perspective view illustrating an overall configuration of a tray apparatus for transferring a substrate according to one embodiment.

FIG. 2 is a perspective view illustrating a state in which a fixed tray and an inner tray constituting the tray apparatus for transferring a substrate according to one embodiment are combined.

FIG. 3 is a perspective view illustrating a state in which a substrate is transferred to and seated on the tray apparatus for transferring a substrate according to one embodiment.

FIG. 4 is an enlarged view illustrating a substrate step formed on the inner tray.

FIG. 5 is a perspective view illustrating a state in which a substrate seated on the tray apparatus for transferring a substrate according to one embodiment is transferred together with the inner tray.

### DESCRIPTION OF THE EMBODIMENTS

The following embodiments are explained in detail with reference to the accompanying drawings, so that those skilled in the art may readily practice the invention. Nevertheless, the invention may be embodied in various forms and is not confined to the specific examples provided herein. Throughout the specification, like reference numerals indicate like elements.

In this specification, the phrase “combinations thereof,” when used in a Markush grouping, refers to any mixture or combination containing at least one of the components listed in the group.

The terms “first,” “second,” “A,” “B,” and similar designations appearing in this specification are used solely to distinguish between elements bearing the same name. Unless the context expressly dictates otherwise, terms in the singular are to be construed as encompassing the plural.

In this specification, the expression “˜-based” denotes a compound that contains the referenced component or a derivative thereof.

As used herein, the phrase “B is located on A” encompasses both situations in which B directly contacts A and situations in which one or more intervening layers are interposed between them; accordingly, it should not be construed as requiring direct contact with the surface of A.

As used herein, the phrase “B is connected to A” embraces both direct connections between A and B and connections made through one or more intermediate components, unless expressly stated otherwise; it should therefore not be construed as requiring a direct link.

Embodiments will now be described in detail with reference to the accompanying drawings.

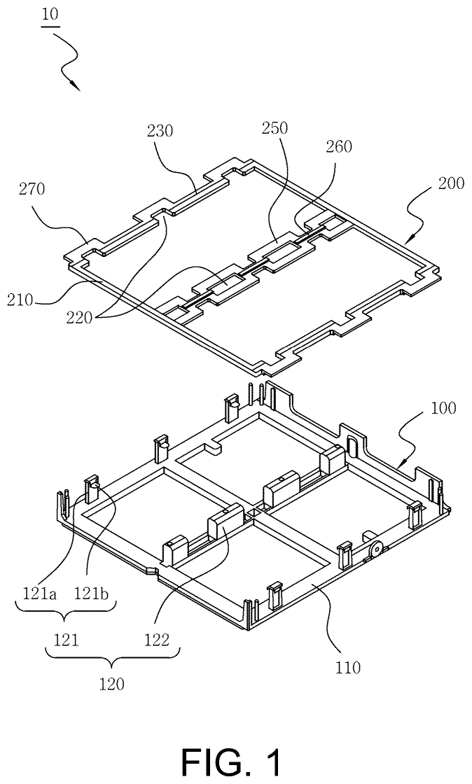

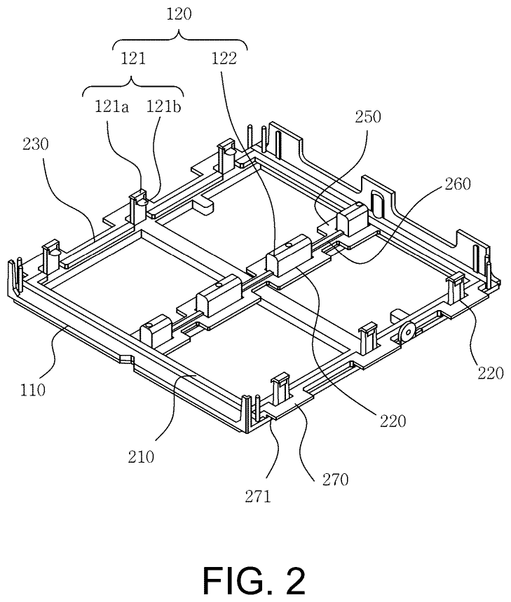

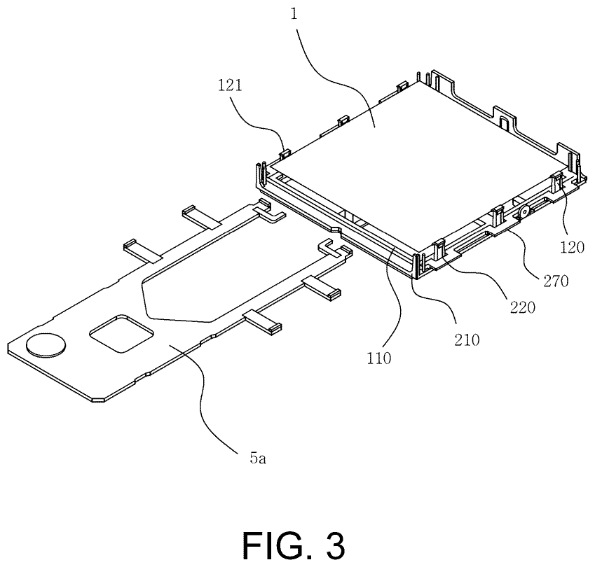

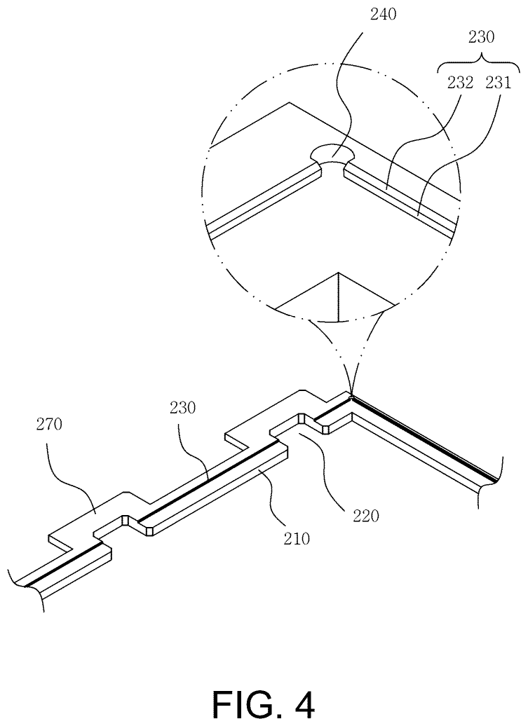

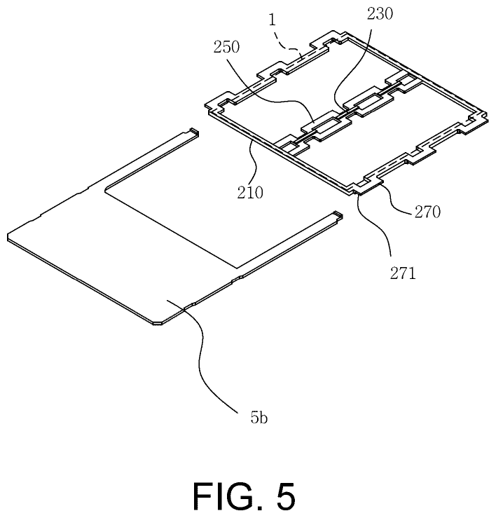

FIG. 1 is an exploded perspective view illustrating an overall configuration of a tray apparatus 10 for transferring a substrate according to one embodiment, FIG. 2 is a perspective view illustrating a state in which a fixed tray 100 and an inner tray 200 constituting the tray apparatus 10 for transferring a substrate according to one embodiment are combined, and FIG. 3 is a perspective view illustrating a state in which a substrate 1 is transferred to and seated on the tray apparatus 10 for transferring a substrate according to one embodiment. In addition, FIG. 4 is an enlarged view illustrating a substrate step 230 formed on the inner tray 200, and FIG. 5 is a perspective view illustrating a state in which a substrate 1 seated on the tray apparatus 10 for transferring a substrate according to one embodiment is transferred together with the inner tray 200.

A tray apparatus 10 for transferring a substrate according to one embodiment is a device that seats a substrate 1 and allows the seated substrate 1 to be transferred by being drawn by a substrate carrier without direct contact with the substrate carrier. Here, the substrate carrier may be, for example, as illustrated in FIG. 3, a first substrate carrier 5a which extracts the substrate 1 from a manufacturing line and seats the substrate 1 on the fixed tray 100, and, as illustrated in FIG. 5, may be a second substrate carrier 5b which lifts the inner tray 200 together with the substrate 1 and transfers them to an inspection stage.

In addition, the first substrate carrier 5a may be set such that a pair of forks have a width smaller than that of the substrate 1 so that the substrate 1 may be directly lifted and transferred, and the second substrate carrier 5b may be set such that a pair of forks have a width larger than that of the substrate 1 so that the substrate 1 may be transferred together with the inner tray 200 by lifting the inner tray 200 to be described later.

The tray apparatus 10 for transferring a substrate according to one embodiment may broadly comprise, as illustrated in FIG. 1, the fixed tray 100 and the inner tray 200.

The fixed tray 100 is a member that seats a substrate 1 transferred by the first substrate carrier 5a while supporting the substrate 1 in a state of being spaced apart by a predetermined height from a fixed frame 110 forming a body of the fixed tray 100. The fixed tray 100 may comprise a fixed frame 110 having a plate shape corresponding to the substrate 1, and, as illustrated in FIG. 3, may seat the substrate 1 while supporting a bottom surface of the substrate 1 in a state of being spaced apart by a predetermined height from the fixed frame 110.

In such a fixed tray 100, for example, in a manufacturing process of a glass substrate, a single substrate 1 extracted by the first substrate carrier 5a for quality inspection may be transferred and seated.

Specifically, as illustrated in FIG. 1, the fixed tray 100 may comprise the fixed frame 110 and seating protrusions 120.

The fixed frame 110 is manufactured in a plate shape having a shape corresponding to the substrate 1 and forms a bottom surface of the tray apparatus 10, and may have a shape and a size corresponding to the substrate 1. For example, the fixed frame 110 may be manufactured as a grid-shaped frame having a plate shape with an area larger than that of the substrate 1 and corresponding to the substrate 1.

It is preferable that the fixed frame 110 be made of a metallic material having rigidity, but it is not limited thereto and may be made of a synthetic resin material such as reinforced plastic or a wooden material.

The seating protrusions 120 are components formed to protrude in a vertical direction from the fixed frame 110 so as to support the substrate 1 in a state of being spaced apart from the fixed frame 110.

The seating protrusions 120 may be formed in plurality and may protrude by a predetermined height from the fixed frame 110, so that the substrate 1 may be seated in a state of being spaced apart by a predetermined height from the fixed frame 110. In addition, the seating protrusions 120 may be fitted into an inner frame 210 constituting the inner tray 200 to be described later, so that the inner tray 200 may be coupled to the fixed tray 100 at a correct position.

Here, the seating protrusions 120 may be manufactured integrally with the fixed frame 110, and, depending on the embodiment, may be fixed to the fixed frame 110 via a separate fixing member such as a fixing bolt.

The inner tray 200 may comprise the inner frame 210 having a plate shape corresponding to the substrate 1, and may be coupled in a state of being stacked on the fixed frame 110 so as to be in a state of being spaced apart from the substrate 1.

That is, the inner frame 210 is coupled in a state of being stacked on the fixed frame 110 before the substrate 1 is seated on the seating protrusions 120, so that, when the substrate 1 is seated on the seating protrusions 120, the inner frame 210 may be spaced apart from the substrate 1.

In addition, after the substrate 1 is seated on the seating protrusions 120, the inner frame 210 is lifted by the second substrate carrier 5b described above, brought into close contact with the bottom surface of the substrate 1, separates the substrate 1 from the fixed tray 100, and may be transferred together with the substrate 1 by the second substrate carrier 5b.

It is preferable that such an inner frame 210 be made of a metallic material having rigidity, but it is not limited thereto and may be made of a synthetic resin material such as reinforced plastic or a wooden material.

Meanwhile, the inner tray 200 may further comprise a protrusion holder 220.

The protrusion holder 220 is a configuration that surrounds an outer periphery of the seating protrusions 120 and is coupled to the seating protrusions 120 such that the seating protrusions 120 are exposed upward when the inner tray 200 is coupled in a state of being stacked on the fixed frame 110.

That is, the protrusion holder 220 is formed in the form of a groove or a hole corresponding to a horizontal cross section (lateral cross section) of the seating protrusions 120, and, in the course of the inner tray 200 being coupled on the fixed frame 110, is fitted to and coupled with the seating protrusions 120 as illustrated in FIG. 2, thereby exposing the seating protrusions 120 in a state of protruding upward.

Accordingly, the inner frame 210 may be stacked on the fixed frame 110 while being fitted to and coupled with the seating protrusions 120 through the protrusion holder 220, and, as illustrated in FIG. 5, may be lifted by the second substrate carrier 5b, brought into close contact with the substrate 1, and transferred together with the substrate 1.

Meanwhile, the seating protrusions 120 may comprise outer protrusions 121 and central protrusions 122.

The outer protrusions 121 are configurations formed to protrude in a vertical direction at an outer peripheral portion of the fixed frame 110 so as to support an outer peripheral portion of the substrate 1 from below and from a lateral side.

The outer protrusions 121 may comprise a protrusion main body 121a and an angle protrusion 121b.

The protrusion main body 121a is a configuration that protrudes by a predetermined height in a vertical direction from an upper surface of the fixed frame 110 and supports the substrate 1 at a predetermined height while forming an angle shape together with the angle protrusion 121b to be described below.

The protrusion main body 121a may be manufactured integrally with the fixed frame 110, or, alternatively, may be fixed to the fixed frame 110 through a separate fixing member.

The angle protrusion 121b protrudes in a horizontal direction at a predetermined height of the protrusion main body 121a and may support an outer peripheral portion of the substrate 1 while forming an angle shape together with the protrusion main body 121a.

Accordingly, the substrate 1 may be supported upward in a state in which an outer peripheral portion thereof is seated on the angle protrusion 121b and is spaced apart from the fixed frame 110, and may be seated in a state in which lateral movement is suppressed, as a side surface of the outer peripheral portion is supported by the protrusion main body 121a.

Meanwhile, the central protrusion 122 is formed to protrude in a vertical direction at a central portion of the fixed frame 110 so as to support a central portion of the substrate 1 from below. Here, a height of the central protrusion 122 may be set to correspond to a height at which the angle protrusion 121b is formed.

Accordingly, as illustrated in FIG. 3, the substrate 1 may be transferred by the first substrate carrier 5a and seated on the outer protrusions 121 in a state of being spaced apart from the fixed frame 110, and may be seated without sagging or warping downward as a central portion thereof is supported by the central protrusion 122.

Although not illustrated, in some embodiments, since the tip of the central protrusion 122 or an upper surface of the angle protrusion 121b comes into direct contact with the substrate 1, a patch of an elastic material may be attached thereto so that an impact is not applied to the substrate 1.

Meanwhile, the inner frame 210 may comprise a central support 250. The central support 250 is formed in a manner of extending across the center of the inner frame 210 so as to provide supporting force, and the above-described protrusion holder 220 is formed thereon so as to be coupled to the central protrusion 122 among the seating protrusions 120.

Here, the protrusion holder 220 formed on the inner frame 210 may, depending on the embodiment, be formed in a groove shape and be coupled to the outer protrusions 121, and the protrusion holder 220 formed on the central support 250 may, depending on the embodiment, be formed in a hole shape and be coupled to the central protrusion 122.

Meanwhile, a sag-preventing protrusion 260 is formed to protrude on an upper surface of the central support 250, and, when the inner frame 210 is raised, the sag-preventing protrusion 260 is brought into close contact with a central portion of a bottom surface of the substrate 1, thereby preventing the central portion of the substrate 1 from sagging or warping.

In addition, the inner tray 200 may comprise a plurality of transfer wings 270 which protrude outward in a horizontal direction from the inner frame 210. The transfer wings 270 are formed to protrude in a horizontal direction from an outer periphery of the inner frame 210 so that the inner frame 210 may be lifted by the second substrate carrier 5b, and thus, as illustrated in FIG. 5, may be drawn by the second substrate carrier 5b. At this time, the transfer wings 270 may be formed so as to surround, from an outer side, the protrusion holders 220 which are coupled to the above-described outer protrusions 121.

Meanwhile, a locking step 271 is formed on a lower surface of each transfer wing 270, so that the transfer wing 270 may be caught by forks of the second substrate carrier 5b and be lifted and transferred without moving in a horizontal direction.

Accordingly, the inner frame 210 is raised by the second substrate carrier 5b coupled to the transfer wings 270 and is brought into close contact with a bottom surface of the substrate 1, and the central support 250 is raised together with the inner frame 210 and is brought into close contact with a central portion of the substrate 1, thereby lifting and transferring the substrate 1.

Meanwhile, as illustrated in FIG. 4, the inner tray 200 may further comprise a substrate step 230.

The substrate step 230 is a component for suppressing horizontal movement of the substrate 1 by supporting both a bottom surface and a side surface of the substrate 1 when the inner frame 210 is raised by the second substrate carrier 5b and is brought into close contact with the substrate 1.

The substrate step 230 may be formed along a circumference of the substrate 1 in a stepped shape forming a level difference on an upper surface of the inner frame 210, and, when the inner tray 200 is raised by the second substrate carrier 5b, may support an outer bottom surface and a side surface of the substrate 1, thereby suppressing horizontal movement of the substrate 1.

Specifically, as enlarged in FIG. 4, the substrate step 230 may comprise a vertical portion 231 and an inclined portion 232.

The vertical portion 231 is a portion that directly supports the side surface of the substrate 1 when the inner frame 210 is brought into close contact with the bottom surface of the substrate 1, and may support the side surface of the substrate 1 while extending in a vertical direction from the upper surface of the inner frame 210 and forming a step at an outer periphery of a contact region of the substrate 1.

The inclined portion 232 is for guiding the substrate 1 to the vertical portion 231 and correctly positioning the substrate 1 when the inner frame 210 is raised, and extends while forming an inclination that opens from an upper end of the vertical portion 231, so that the substrate 1 is guided along an inclined surface, thereby preventing damage to the substrate 1 and allowing the substrate 1 to be correctly positioned in a state of being supported by the vertical portion 231.

Meanwhile, a rounded portion 240 may be formed at a corner portion of the substrate step 230.

The rounded portion 240 is for preventing a corner portion of the substrate 1, whose side surface comes into close contact with the substrate step 230, from being damaged, and, as illustrated in FIG. 4, is formed in a circular shape at the corner portion of the substrate step 230, so that a horizontal portion and a vertical portion of the substrate step 230 can be spaced apart from each other.

Accordingly, in the course of the substrate 1 coming into close contact with the substrate step 230, a corner portion of the substrate 1 is positioned at the rounded portion 240, so that the corner portion does not come into close contact with the substrate step 230, and damage to the corner is prevented.

That is, when the inner tray 200 is raised by the second substrate carrier 5b, the inner tray 200 may transfer the substrate 1 while supporting an outer peripheral portion of the substrate 1 through the inner frame 210, supporting a central portion of the substrate 1 through the sag-preventing protrusion 260 protruding from the central support 250, and supporting a side surface of the substrate 1 through the substrate step 230.

Here, the inner tray 200 is formed of a frame having a frame shape, and thus may support a dummy region, such as an outer peripheral portion, which is not a product region among regions of the substrate 1, while allowing transmission of light, and thereby, when the substrate 1 is formed as a glass semiconductor substrate, may allow inspection of the substrate 1 by an optical device even while the substrate 1 is supported.

Operation and actions of the tray apparatus 10 for transferring a substrate according to one embodiment including the components as described above will be described by way of example of an inspection process of a glass substrate.

In the course of the inner tray 200 being coupled to the fixed tray 100, the seating protrusions 120 of the fixed tray 100 pass through the protrusion holders 220 of the inner tray 200, and the inner tray 200 is stacked at a correct position on the fixed frame 110.

When the substrate 1 is to be inspected, the first substrate carrier 5a extracts a single substrate 1 from a manufacturing line of the substrate 1, transfers the substrate 1, and seats the substrate 1 on the seating protrusions 120 of the fixed tray 100. At this time, the first substrate carrier 5a, after transferring the substrate 1 in a state in which the substrate 1 is horizontally arranged on forks, slowly descends and positions the substrate 1 on the seating protrusions 120 exposed on the fixed tray 100 on which the inner tray 200 is stacked.

When the substrate 1 is seated at a correct position, the first substrate carrier 5a further descends and is separated from the substrate 1, and passes through a spaced region between the inner tray 200 and the seating protrusions 120.

Accordingly, the substrate 1 may be seated in a state of being spaced apart from the inner tray 200 while being seated on the outer protrusions 121, and may be seated without sagging or warping downward as a central portion thereof is supported by the central protrusion 122. In addition, the substrate 1 may be seated in a state in which horizontal movement is suppressed, as an outer peripheral portion thereof is seated on the angle protrusion 121b and a side surface of the outer peripheral portion is supported by the protrusion main body 121a.

Meanwhile, when the substrate 1 is to be transferred together with the inner tray 200, the second substrate carrier 5b slowly rises from below the inner tray 200, lifts the inner tray 200, separates the substrate 1 from the fixed tray 100, and transfers the inner tray 200 together with the substrate 1 to an inspection stage.

At this time, the second substrate carrier 5b draws the transfer wings 270 and raises the inner frame 210, and brings the inner frame 210 into close contact with a bottom surface of the substrate 1. In this process, the substrate step 230 guides the substrate 1 to the vertical portion 231 through the inclined portion 232, correctly positions and brings the substrate 1 into close contact with the vertical portion 231, and the sag-preventing protrusion 260 of the central support 250 pushes and supports a central portion of the substrate 1.

Accordingly, the substrate 1 may be separated from the fixed tray 100 while being raised together with the inner tray 200 in a state of being supported by the inner tray 200, and may be transferred to the inspection stage by the second substrate carrier 5b to perform an inspection process.

At this time, since a dummy region, which is not a product region, of the substrate 1 is supported by the inner tray 200, the inspection process can be performed by an optical device in a state in which the substrate 1 is supported by the inner tray 200.

At this time, shapes of the first substrate carrier 5a and the second substrate carrier 5b are merely examples and may be formed in other shapes, and, for example, the second substrate carrier 5b may lift the inner tray 200 in such a manner as to grip the transfer wings 270 from above and below, instead of drawing the transfer wings 270 from below.

As described above, in a tray apparatus 10 for transferring a substrate according to one embodiment, the substrate 1 is seated through the fixed tray 100, and the substrate 1 can be separated from the fixed tray 100 through the inner tray 200 that is raised by the second substrate carrier 5b, so that the substrate 1 may be transferred without direct contact with the second substrate carrier 5b, thereby enabling rapid inspection while preventing damage.

According to any one of the above-described means for solving the problems, it is possible to provide a tray apparatus for transferring a substrate, which allows the substrate to be safely transferred without a risk of the substrate being contaminated or damaged in the course of transfer of the substrate.

According to any one of the above-described means for solving the problems, it is possible to provide a tray apparatus for transferring a substrate, in which a seating region for the substrate is provided through the fixed tray, and the substrate is separated from the fixed tray through the inner tray that is raised by a substrate carrier, so that the substrate may be transferred without direct contact with the substrate carrier.

According to any one of the above-described means for solving the problems, it is possible to provide a tray apparatus for transferring a substrate, which allows an optical inspection to be safely performed while the substrate is seated on the inner tray.

According to any one of the above-described means for solving the problems, it is possible to provide a tray apparatus for transferring a substrate, in which the substrate can be seated in a state of being spaced apart from a bottom surface through seating protrusions constituting the fixed tray, and in which protrusion holders constituting the inner tray are formed in the shape of grooves or holes and accommodate the seating protrusions inside the grooves or holes, so that the inner tray can be disposed under the substrate in a state of being stacked on the fixed tray.

According to any one of the above-described means for solving the problems, it is possible to prevent lateral movement of the substrate by supporting side surfaces of the substrate through a substrate step provided in the inner tray, and thus damage to the substrate due to movement of the substrate in the course of transferring the substrate can be prevented.

According to any one of the above-described means for solving the problems, it is possible that, in the course of the inner tray being raised, the side surfaces of the substrate are guided to the vertical portion through the inclined portion constituting the substrate step, so that the side surfaces of the substrate are supported in a state of being correctly positioned at the vertical portion with movement being prevented.

According to any one of the above-described means for solving the problems, since the corner portions of the substrate are spaced apart from the substrate step by a rounded portion formed at corner portions of the substrate step, it is possible to prevent corner portions of the substrate from being damaged in the course of the inner tray supporting the substrate.

According to any one of the above-described means for solving the problems, since the inner tray supports an outer peripheral portion of the substrate through the inner frame and supports a central portion of the substrate through a sag-preventing protrusion formed on an upper surface of the central support, warpage or sagging of the substrate can be prevented.

According to any one of the above-described means for solving the problems, since the inner tray supports the substrate while supporting an outer peripheral portion or a dummy region of a central portion, which are not product regions, it is possible to rapidly perform precise inspection of the substrate because inspection by an optical device is possible in a state in which the substrate is placed on the inner tray.

Furthermore, according to any one of the above-described means for solving the problems, only the substrate may be separated from the tray apparatus by changing a configuration of the substrate carrier as necessary, or the substrate may be separated together with the inner tray in a state in which the substrate is seated on the inner tray.

The effects obtainable from the embodiments disclosed herein are not limited to the effects mentioned above, and other effects not mentioned will be clearly understood by those skilled in the art to which the embodiments disclosed herein pertain from the following description.

The above-described embodiments are given by way of example, and it will be understood by those skilled in the art to which the embodiments pertain that various modifications in other specific forms can be easily made without changing the technical spirit or essential characteristics of the above-described embodiments. Therefore, the above-described embodiments should be understood as being illustrative in all respects and not restrictive. For example, respective components described as being in a single body may be implemented in a distributed manner, and likewise, components described as being distributed may be implemented in a combined form.

The scope to be protected by the present specification is indicated by the claims described below rather than by the foregoing detailed description, and should be construed as including all modified or altered forms derived from the meaning and scope of the claims and equivalents thereof.

What is claimed is:

1. A tray apparatus for transferring a substrate, comprising:
a fixed tray comprising a plate-shaped fixed frame having a shape corresponding to the substrate, and configured to seat the substrate while supporting a bottom surface of the substrate in a state of being spaced apart by a predetermined height from the fixed frame; and
an inner tray comprising a plate-shaped inner frame corresponding to the substrate, the inner tray being coupled in a state of being stacked on the fixed frame so as to be in a state of being spaced apart from the substrate, the inner frame being brought into close contact with the bottom surface of the substrate while being lifted by a substrate carrier so as to separate the substrate from the fixed tray, and the inner tray being transferred together with the substrate by the substrate carrier.

2. The tray apparatus for transferring a substrate according to claim 1,
wherein the fixed tray further comprises a plurality of seating protrusions which are formed to protrude in a vertical direction from the fixed frame and support the substrate in a state of being spaced apart from the fixed frame.

3. The tray apparatus for transferring a substrate according to claim 2,
wherein the inner tray further comprises a protrusion holder which is formed in the inner frame as a groove or a hole corresponding to a horizontal cross section of the seating protrusions, and which surrounds an outer periphery of the seating protrusions and is coupled to the seating protrusions such that the seating protrusions are exposed upward when the inner tray is coupled in a state of being stacked on the fixed frame.

4. The tray apparatus for transferring a substrate according to claim 3,
wherein the seating protrusions comprise outer protrusions which are formed to protrude in a vertical direction at an outer periphery of the fixed frame and support an outer peripheral portion of the substrate from below and from a lateral side.

5. The tray apparatus for transferring a substrate according to claim 4,
wherein the outer protrusions comprise:
a protrusion main body which protrudes by a predetermined height in a vertical direction from an upper surface of the fixed frame; and
an angle protrusion which protrudes in a horizontal direction at a predetermined height of the protrusion main body and supports the outer peripheral portion of the substrate while forming an angle shape together with the protrusion main body.

6. The tray apparatus for transferring a substrate according to claim 5,
wherein the seating protrusions further comprise a central protrusion which is formed to protrude in a vertical direction at a central portion of the fixed frame and supports a central portion of the substrate from below,
and a height of the central protrusion corresponds to a height at which the angle protrusion is formed.

7. The tray apparatus for transferring a substrate according to claim 3,
wherein the inner frame comprises a central support which is formed in a manner of extending across a center of the inner frame and on which the protrusion holder is formed,
and the central support comprises a sag-preventing protrusion which is formed to protrude on an upper surface and prevents sagging of a central portion of a bottom surface of the substrate by being brought into close contact with the central portion of the bottom surface of the substrate when the inner frame is raised.

8. The tray apparatus for transferring a substrate according to claim 1,
wherein the inner tray further comprises a substrate step which is formed in a stepped shape to form a level difference on an upper surface of the inner frame along a circumference of the substrate, and which supports a side surface of the substrate and suppresses lateral movement of the substrate in the course of raising of the inner tray by the substrate carrier.

9. The tray apparatus for transferring a substrate according to claim 8,
wherein the substrate step comprises:
a vertical portion which extends in a vertical direction from the upper surface of the inner frame and supports the side surface of the substrate; and
an inclined portion which extends while forming an incline from the vertical portion and guides the substrate toward the vertical portion when the inner frame is raised.

10. The tray apparatus for transferring a substrate according to claim 8,
wherein the inner tray further comprises a rounded portion which is formed in a circular shape at a corner portion of the substrate step and spaces a corner portion of the substrate apart from the substrate step.

11. The tray apparatus for transferring a substrate according to claim 4,
wherein the inner tray further comprises transfer wings which are formed to protrude outward in a horizontal direction from the inner frame and are drawn by the substrate carrier when being transferred by the substrate carrier.

12. The tray apparatus for transferring a substrate according to claim 11,
wherein the transfer wings are formed so as to surround, from an outer side, the protrusion holder which is coupled to the outer protrusions.

13. The tray apparatus for transferring a substrate according to claim 1,
wherein the substrate is a glass core or a semiconductor packaging substrate comprising a glass core,
and the inner tray supports a dummy region, which is not a product region, among regions of the substrate, and allows inspection of the substrate by an optical device.
